(19) United States
(12) Patent Application Publication
(10) Pub. No.: US 2018/0358423 A1
(43) Pub. Date: Dec. 13, 2018

(54) DISPLAY DEVICE

(71) Applicant: Japan Display Inc., Minato-ku (JP)

(72) Inventor: Jun HANARI, Minato-ku (JP)

(73) Assignee: Japan Display Inc., Minato-ku (JP)

(21) Appl. No.: 15/988,425

(22) Filed: May 24, 2018

(30) Foreign Application Priority Data
Jun. 7, 2017 (JP) 2017-112243

(51) Int. Cl. H01L 27/32; G09G 3/3225; H01L 51/52

(52) U.S. Cl. CPC H01L 27/3276; H01L 27/3262; H01L 51/5237; H01L 51/5206; H01L 51/5221; G09G 3/3225

(57) ABSTRACT

A display device according to an embodiment of the present invention includes: a base material having a display area including pixels and a peripheral area located outside of the display area; a pair of wires extending in a first direction from an end part to the display area of the base material in the peripheral area; and a second wire located between the pair of wires in the peripheral area. A power supply voltage to be supplied to the pixels is applied to the pair of wires, the power supply voltage to be supplied to the pixels is not applied to the second wire, and one of the pair of wires has a first bending portion, the other of the pair of wires has a second bending portion, and the second wire has a third bending portion and the respective bending portions bend in the same direction as one another.

### CROSS-REFERENCE TO RELATED APPLICATION

The present application claims priority from Japanese Application JP2017-112243 filed on Jun. 7, 2017, the content of which is hereby incorporated by reference into this application.

### BACKGROUND OF THE INVENTION

### 1. Field of the Invention

One or more embodiments of the present invention relate to a display device.

### 2. Description of the Related Art

In a display device including a display area such as an organic electroluminescence (EL) display device and a liquid crystal display device, recently, development of a flexible display having a bendable display panel using a base material having flexibility has been advanced.

For example, as disclosed in JP 2016-31499 A, it is proposed that amounting part of an integrated circuit (IC) and a flexible printed circuit board (FPC) are bended toward the back side of the display area, and thereby, the frame is made thinner.

### SUMMARY OF THE INVENTION

For example, a wire is placed on the base material in the display panel. However, the display panel may be broken due to heat generation by the wire near the above described bending area.

One or more embodiments of the present invention have been made in view of the above, and an object thereof is to provide a display device with a suppressed adverse effect due to heat generation by the wire in the bending area.

A display device according to an embodiment of the present invention includes: a base material having a display area including a plurality of pixels and a peripheral area located outside of the display area; a pair of wires extending in a first direction from an end part of the base material to the display area of the base material in the peripheral area; and a second wire located between the pair of wires in the peripheral area. A power supply voltage to be supplied to the plurality of pixels is applied to the pair of wires, the power supply voltage to be supplied to the plurality of pixels is not applied to the second wire, and one of the pair of wires has a first bending portion, the other of the pair of wires has a second bending portion, and the second wire has a third bending portion, the first, second, and third bending portions bending in the same direction as one another.

A display device according to another embodiment of the present invention includes: a base material having a display area including a plurality of pixels and a peripheral area located outside of the display area; a pair of wires extending in a direction from an end part of the base material to the display area of the base material in the peripheral area; and a second wire located between the pair of wires in the peripheral area. A voltage to be supplied to the plurality of pixels is applied to the pair of wires, the voltage to be supplied to the plurality of pixels is not applied to the second wire, the base material has a bending area in which the base material is curved in the peripheral area, and one of the pair of wires has a first bending portion, the other of the pair of wires has a second bending portion, and the second wire has a third bending portion in the bending area, the first, second, and third bending portions bending in the same direction as one another.

### BRIEF DESCRIPTION OF THE DRAWINGS

FIG. 1 is a schematic diagram showing a schematic configuration of an organic EL display device according to the first embodiment of the invention.

FIG. 2 is a schematic plan view showing an example of a display panel of the organic EL display device shown in FIG. 1.

FIG. 3 shows an example of a section along in FIG. 2.

FIG. 4A is a plan view showing an example of an arrangement state of wires contained in a circuit layer of an area A surrounded by a broken line in FIG. 2.

FIG. 4B shows an example of a section along B-B in FIG. 4A.

FIG. 5A is a plan view showing an example of an arrangement state of wires contained in a circuit layer in the second embodiment of the invention.

FIG. 5B shows an example of a section along B-B in FIG. 5A.

FIG. 6A is a plan view showing an example of an arrangement state of wires contained in a circuit layer in the third embodiment of the invention.

FIG. 6B shows an example of a section along B-B in FIG. 6A.

FIG. 7A is a plan view showing an example of an arrangement state of wires contained in a circuit layer in the fourth embodiment of the invention.

FIG. 7B shows an example of a section along B-B in FIG. 7A.

### DETAILED DESCRIPTION OF THE INVENTION

As below, embodiments of the invention will be explained with reference to the drawings. Note that disclosures are only examples, and the matter readily conceivable with respect to appropriate changes by a person skilled in the art while keeping the spirit of the invention may naturally fall within the scope of the invention. Further, for clearer explanation, the drawings may be schematically described regarding widths, thicknesses, shapes, etc. of the respective parts compared to the actual forms, however, these are only examples and do not limit the interpretation of the invention. In the specification and the respective drawings, the same elements as those described in relation to the previously mentioned drawings may have the same signs and the detailed explanation may be omitted as appropriate.

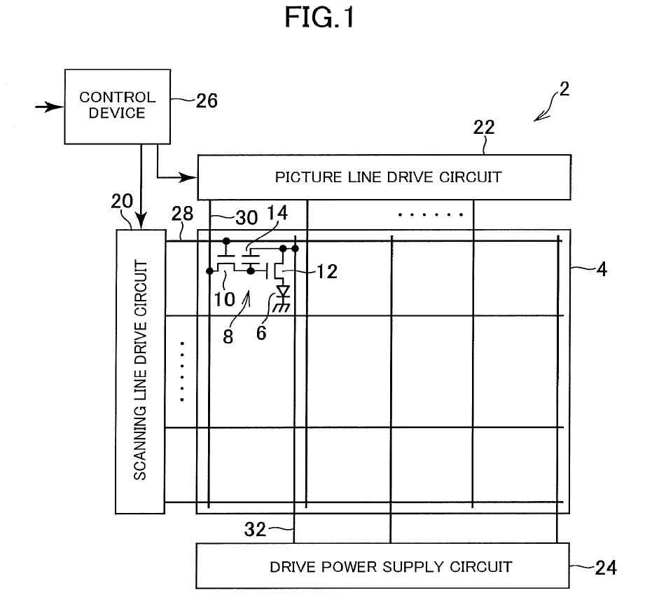

FIG. 1 is a schematic diagram showing a schematic configuration of a display device according to the first embodiment of the invention using an organic EL display device as an example. An organic EL display device 2 includes a pixel array unit 4 that displays an image and a drive unit that drives the pixel array unit 4. The organic EL display device 2 is a flexible display using a resin film as a base material and a stacking structure such as thin-film transistors (TFTs) and organic light emitting diodes (OLEDs) are formed on the base material formed by the resin film. Note that the schematic diagram shown in FIG. 1 is only an example and the embodiment is not limited to that.

In the pixel array unit 4, OLEDs 6 and pixel circuits 8 are arranged in a matrix form in correspondence with the pixels. The pixel circuit 8 includes a plurality of TFTs 10, 12 and a capacitor 14.

The drive unit includes a scanning line drive circuit 20, a picture line drive circuit 22, a drive power supply circuit 24, and a control device 26, and drives the pixel circuit 8 and controls light emission of the OLED 6.

The scanning line drive circuit 20 is connected to scanning signal lines 28 each provided for the respective horizontal lines of the pixels (pixel rows). The scanning line drive circuit 20 sequentially selects the scanning signal line 28 according to a timing signal input from the control device 26, and applies a voltage for turning on the lighting TFT 10 to the selected scanning signal line 28.

The picture line drive circuit 22 is connected to picture signal lines 30 each provided for the respective vertical lines of the pixels (pixel columns). A picture signal is input from the control device 26 to the picture line drive circuit 22, and the circuit outputs a voltage according to the picture signal of the selected pixel row to the respective picture signal line 30 in response to the selection of the scanning signal line 28 by the scanning line drive circuit 20. The voltage is written in the capacitor 14 via the lighting TFT 10 in the selected pixel row. The drive TFT 12 supplies a current according to the written voltage to the OLED 6, and thereby, the OLED 6 of the pixel corresponding to the selected scanning signal line 28 emits light.

The drive power supply circuit 24 is connected to drive power supply lines 32 each provided for the respective pixel columns, and supplies the current to the OLED 6 via the drive power supply line 32 and the drive TFT 12 of the selected pixel row.

Here, the lower electrode of the OLED 6 is connected to the drive TFT 12. On the other hand, the upper electrode of the respective OLEDs 6 are formed by an electrode in common with the OLEDs 6 of all pixels. When the lower electrode is formed as an anode, a higher potential is input thereto and the upper electrode serves as a cathode and a lower potential is input thereto. When the lower electrode is formed as a cathode, lower potentials are input thereto and the upper electrode serves as an anode and a higher potential is input thereto.

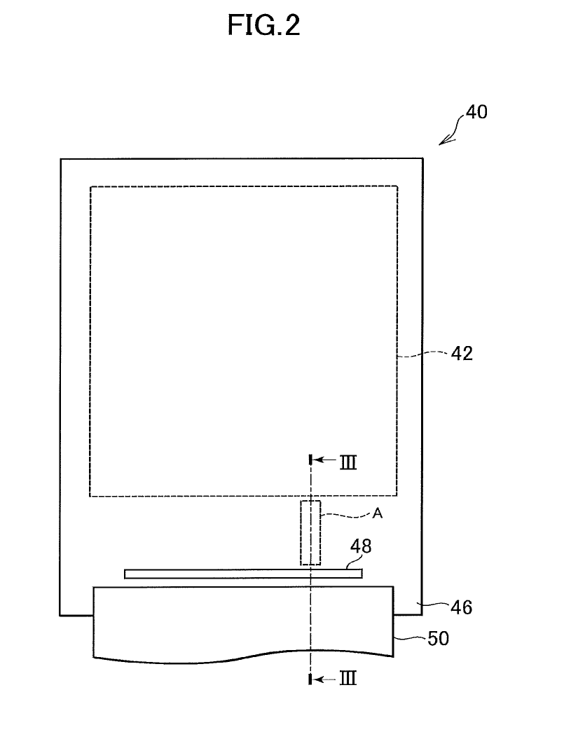

FIG. 2 is a schematic plan view showing an example of a display panel of the organic EL display device shown in FIG. 1. In a display area 42 of a display panel 40, the pixel array unit 4 shown in FIG. 1 is provided and the OLEDs 6 are arranged in the pixel array unit 4 as described above. As described above, the upper electrode forming the OLEDs 6 is formed in common with the respective pixels and covers the whole display area 42.

A component mounting area 46 is provided in one side of the display panel 40 having a rectangular shape, and a wire connected to the display area 42 are placed therein. A driver IC 48 forming the drive unit is mounted on and the FPC 50 is connected to the component mounting area 46. The FPC 50 is connected to the control device 26 and the other circuits 20, 22, 24, etc., and an IC is mounted thereon.

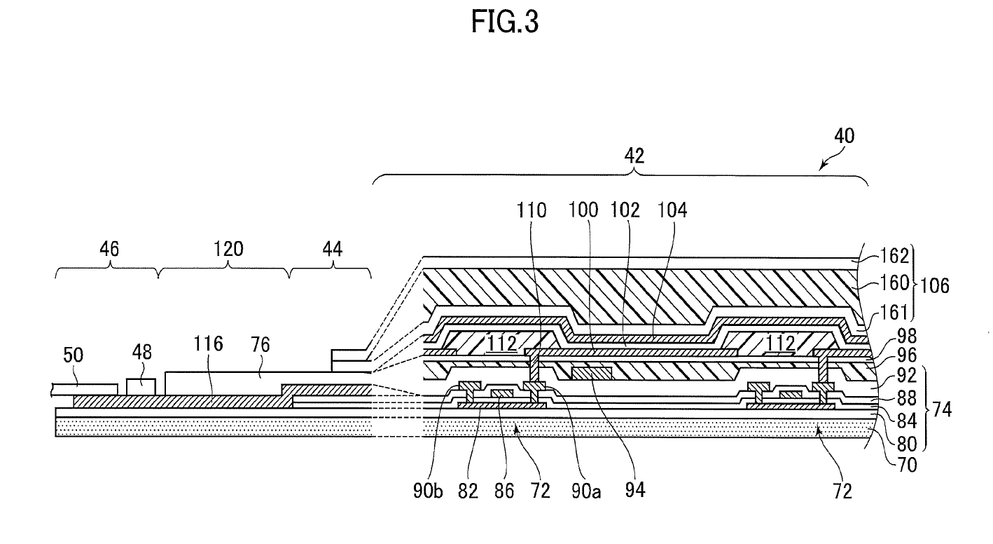

FIG. 3 shows an example of a section along in FIG. 2. The display panel 40 has a structure in which a circuit layer 74 with a TFT 72 etc. formed thereon, the OLED 6, and a sealing layer 106 sealing the OLED 6 are stacked on a base material 70 formed by a resin film. As the resin forming the base material 70, e.g. a polyimide-based resin is used. The thickness of the base material 70 is e.g. from 10 μm to 20 μm. A protective layer (not shown) is formed on the sealing layer 106. In the embodiment, the pixel array unit 4 is of a top emission type and the light generated in the OLED 6 is output to the opposite side to the base material 70 (upward in FIG. 3). Note that, in the case where a color filter system is used as the coloring system in the organic EL display device 2, for example, a color filter is placed between the sealing layer 106 and the protective layer (not shown) or on the side of a counter substrate. The white light generated in the OLED 6 is passed through the color filter, and thereby, e.g. red (R), green (G), blue (B) lights are generated.

In the circuit layer 74 of the display area 42, the above described pixel circuit 8, a scanning signal line 28, a picture signal line 30, a drive power supply line 32, etc. are formed. At least a part of the drive unit may be formed in an area adjacent to the display area 42 as the circuit layer 74 on the base material 70. As described above, the driver IC 48 forming the drive unit and the FPC 50 may be connected to a wire 116 of the circuit layer 74 in the component mounting area 46.

As shown in FIG. 3, a foundation layer 80 formed using an inorganic insulating material is placed on the base material 70. As the inorganic insulating material, e.g. silicon nitride (SiN_{y}), silicon oxide (SiOₓ), and a complex thereof may be used. The foundation layer 80 may have a single-layer structure or stacking structure.

In the display area 42, a semiconductor region 82 serving as a channel part and a source/drain part of a top-gate TFT 72 are formed via the foundation layer 80 on the base material 70. The semiconductor region 82 is formed using e.g. polysilicon (p-Si). For example, a semiconductor layer (p-Si film) is provided on the base material 70 and the semiconductor layer is patterned so that the portion used in the circuit layer 74 may be selectively left, and thereby, the semiconductor region 82 is formed.

A gate electrode 86 is placed via a gate insulating film 84 on the channel part of the TFT 72. The gate insulating film 84 is representatively formed using TEOS. The gate electrode 86 is formed by patterning of a metal film formed by sputtering or the like, for example. An interlayer insulating layer 88 is placed to cover the gate electrode 86 on the gate electrode 86. The interlayer insulating layer 88 is formed using e.g. the inorganic insulating material. In the semiconductor region 82 (p-Si) serving as the source/drain part of the TFT 72, an impurity is introduced by ion implantation, further, a source electrode 90a and a drain electrode 90b electrically connected thereto are formed, and thereby, the TFT 72 is formed.

An interlayer insulating film 92 is placed on the TFT 72. A wire 94 is placed on the surface of the interlayer insulating film 92. The wire 94 is formed by patterning of a metal film formed by sputtering or the like, for example. For example, the wire 116 and the scanning signal line 28, the picture signal line 30, and the drive power supply line 32 shown in FIG. 1 may be formed by a multilayer wiring structure using the metal film forming the wire 94 and the metal film used for formation of the gate electrode 86, the source electrode 90a, and the drain electrode 90b. On the structure, a planarizing film 96 and a passivation film 98 are formed using a resin material or the like and, in the display area 42, the OLED 6 is formed on the passivation film 98. The passivation film 98 is formed using e.g. an inorganic insulating material such as SiN_{y}.

The OLED 6 includes a lower electrode 100, an organic material layer 102, and an upper electrode 104. Specifically, the organic material layer 102 includes a hole transport layer, a light emission layer, an electron transport layer, etc. The OLED 6 is representatively formed by stacking of the lower electrode 100, the organic material layer 102, and the upper electrode 104 from the base material 70 side in this order. In the embodiment, the lower electrode 100 serve as the anode of the OLED 6 and the upper electrode 104 serves as the cathode thereof.

If the TFT 72 shown in FIG. 3 is the drive TFT 12 having a n-channel, the lower electrode 100 is connected to the source electrode 90a of the TFT 72. Specifically, after the formation of the above described planarizing film 96, a contact hole 110 for connection of the lower electrode 100 to the TFT 72 is formed, and the lower electrode 100 connected to the TFT 72 is formed for the respective pixels by patterning of a conducting part 111 formed on the surface of the planarizing film 96 and inside the contact hole 110, for example. The lower electrode is formed using e.g. a transmissive conducting material including ITO (Indium Tin Oxide) and IZO (Indium Zinc Oxide), a metal including Ag and Al.

On the structure, a rib 112 for separating the pixels are placed. For example, after the formation of the lower electrode 100, the rib 112 is formed in the boundary between the pixels, and the organic material layer 102 and the upper electrode 104 are stacked in the effective region (the region in which the lower electrode 100 is exposed) of the pixel surrounded by the rib 112. The upper electrode 104 is formed using e.g. an ultrathin alloy of Mg and Ag and a transmissive conducting material including ITO and IZO.

On the upper electrode 104, the sealing layer 106 is placed to cover the whole display area 42. The sealing layer 106 has a stacking structure including a first sealing film 161, a sealing planarization film 160, and a second sealing film 162 in this order. The first sealing film 161 and the second sealing film 162 are formed using an inorganic material (e.g. inorganic insulating material). Specifically, the film is formed by deposition of a SiN_{y} film using chemical vapor deposition (CVD). The sealing planarization film 160 is formed using an organic material (e.g. a resin material including a curable resin composition). On the other hand, the sealing layer 106 is not placed in the bending area 120 and the component mounting area 46.

An insulating layer 76 is formed on the wire 116 (drive power supply line 32, scanning signal line 28, and picture signal line 30). The insulating layer 76 is formed, for example, when the inorganic insulating film (e.g. interlayer insulating layer 88, interlayer insulating film 92, passivation film 98) and/or the resin film (e.g. planarizing film 96) are formed.

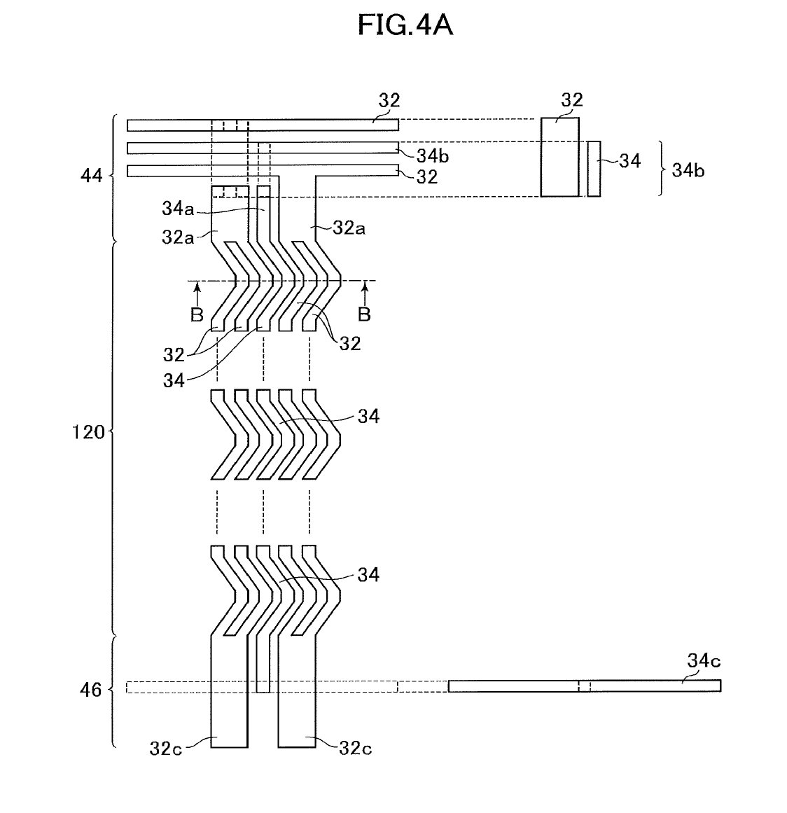

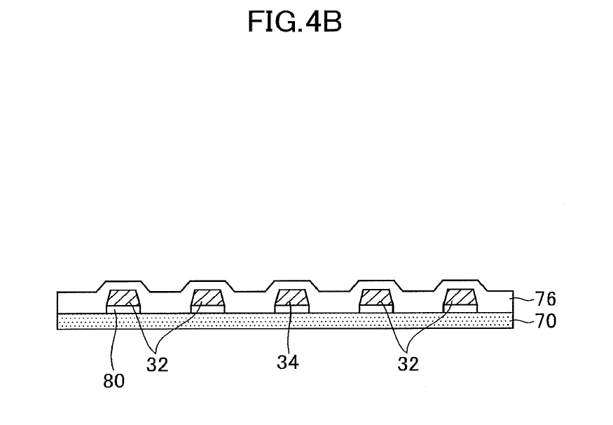

FIG. 4A is a plan view showing an example of an arrangement state of wires contained in the circuit layer of an area A surrounded by a broken line in FIG. 2, and FIG. 4B shows an example of a section along B-B in FIG. 4A. Specifically, FIG. 4A shows the arrangement state of the wires of the layers contained in the circuit layer 74 in a frame area 44, a bending area 120, and the component mounting area 46, and shows the layers under the insulating layer 76 on the left and the layers on the insulating layer 76 on the right. The frame area 44 is an area surrounding the display area 42 and different from the display area 42 in that the frame area 44 does not contain the TFT 72 or OLED 6, for example. As shown in FIG. 3, the display panel 40 may be manufactured with the base material 70 held flat, however, for example, when the panel is housed in the housing of the organic EL display device 2, the bending area 120 is provided outside of the display area 42, and the component mounting area 46 is placed on the back side of the display area 42.

In the bending area 120, it is preferable to omit or thin at least part of the layers formed using an inorganic insulating material (e.g. foundation layer 80, interlayer insulating layer 88, interlayer insulating film 92, passivation film 98). This is because the layers formed using an inorganic insulating material tend to be broken by bending. In the illustrated example, in the bending area 120, the foundation layer 80 is selectively formed in locations in which the drive power supply line 32 (wire 116) is placed (specifically, formed by patterning of an inorganic insulating film formed by CVD or the like by etching or the like), however, the foundation layer 80 may be omitted substantially entirely and the drive power supply line 32 (wire 116) may be placed directly on the base material 70.

For example, to deal with bending (deformation stress) of the display panel 40, in the bending area 120, the drive power supply line 32 (wire 116) has a wavy bending shape. As the bending shape, not only the illustrated wavy shape but also e.g. a grating or mesh shape is employed.

The drive power supply line 32 generally has a linear shape and a wire width set to a wider width in several hundreds of micrometers to several millimeters. On the other hand, the wire width of the bending area 120 is set to a narrower width in several micrometers to dozen micrometers. As shown in FIG. 4A, in the bending area 120, the width of the drive power supply line 32 changes from the wider width to the narrower width.

In the bending area 120, a heat dissipation wire 34 extending in the extension direction of the drive power supply line 32 and having a bending shape is placed in parallel to the drive power supply line 32. According to the bending shape, the bending (deformation stress) of the display panel 40 may be dealt with and fracture may be suppressed. In the illustrated example, the heat dissipation wire 34 has the same shape as the drive power supply line 32 and is placed with a predetermined gap between one drive power supply line 32 and the other drive power supply line 32. Specifically, the heat dissipation wire 34 is formed in a wavy shape and has a width set to several micrometers to dozen micrometers.

In the bending area 120, for example, the wire lengths are extended by the bending of the drive power supply line 32 (wire 116) and the wire resistance increases. Further, when the higher brightness and the larger screen of display are requested, electric power necessary for the display increases and the amount of current also increases. In addition, in the organic EL display panel, the area that can be connected to the wire 116 may be restricted (for example, it may be impossible to set the area to the width or more of the display area 42). Accordingly, in the bending area 120, the adverse effect due to heat generation by the drive power supply line 32 is readily caused (for example, between the positive to negative wiring of the power supply). Particularly, heat may be generated locally in the part in which the shape is changed to the narrower width and/or bending shape (specifically, the location several millimeters ahead from the part in which the shape is changed to the narrower width and/or bending shape). As described above, the heat dissipation wire 34 is placed, and thereby, heat dissipation may be promoted and the adverse effect due to heat generation may be suppressed. Further, according to the placement of the heat dissipation wire 34, for example, compared to the form provided with another member such as a heatsink, limitations on the structure are harder to be imposed and the structure may contribute to suppression of the manufacturing cost and decrease in thickness of the panel.

In the illustrated example, the heat dissipation wire 34 changes from the bending shape to the linear shape in correspondence with the part in which the wire width and shape of the drive power supply line 32 change. Heat may be also dissipated in a linear portion 34a. The heat dissipation is lower in the wider portion 32a of the drive power supply line 32 placed adjacent to the linear portion 34a, and thereby, effective heat dissipation is expected in the linear portion 34a.

As shown in FIG. 4A, in the frame area 44, the drive power supply line 32 is placed along the periphery of the display area 42, and the heat dissipation wire 34 is routed with a predetermined gap from the line. Specifically, as shown in FIG. 4A, the heat dissipation wire 34 is routed via the insulating layer 76 over the single drive power supply line 32. Here, the heat dissipation wire 34 may be allowed to function as e.g. a ground wire or circuit control wire. A routing portion 34b of the heat dissipation wire 34 is placed in the frame area 44 (on the display area 42 side), and thereby, the routing portion 34b may function as a heatsink and, for example, may effectively dissipate heat in the above described part in which the shape is changed to the narrower width and/or bending shape.

The drive power supply line 32 is extended to the opposite side to the display area 42 (the component mounting area 46 side) and the heat dissipation wire 34 is routed onto the insulating layer 76. Here, the routing portion 34c of the heat dissipation wire 34 may be connected to extension portion 32c of the drive power supply line 32 and another branch wire. On the opposite side to the display area 42, the wiring area is easily secured and the routing portion 34c is sufficiently secured, and that contributes to improvement in heat dissipation of the heat dissipation wire 34. Note that, for example, in the case where the wiring area may be sufficiently secured, the heat dissipation wire 34 may be also routed in the frame area 44 in a layer different from the drive power supply line 32.

In the embodiment, as shown in FIG. 4B, the insulating layer 76 is formed to integrally cover the plurality of wires (the drive power supply line 32 and the heat dissipation wire 34), however, the parallel wires may be covered individually by insulating layers 76.

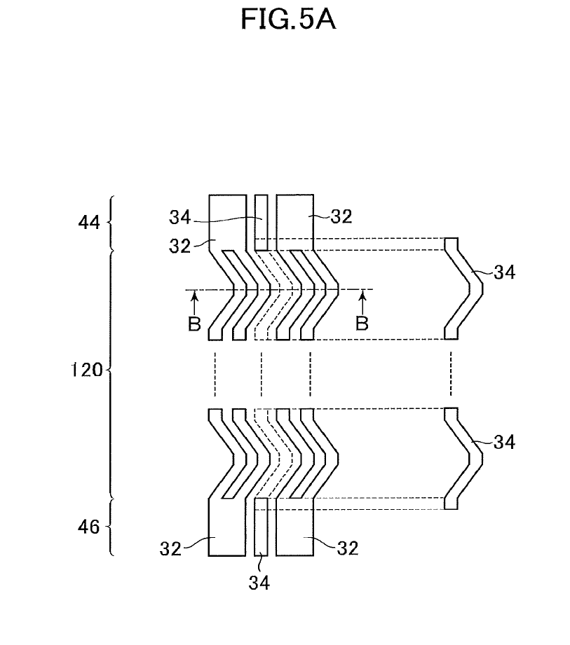

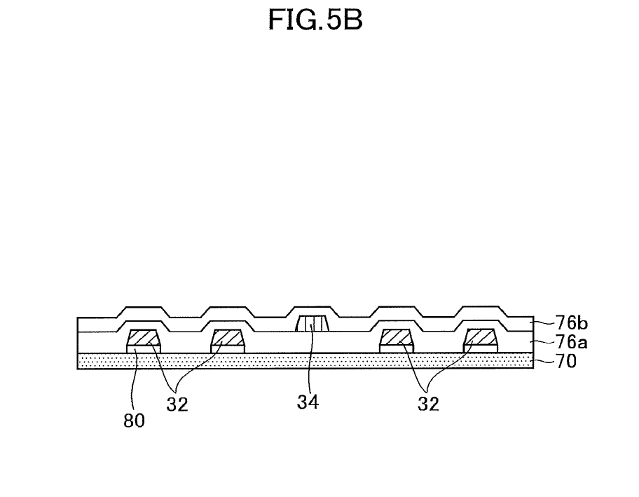

FIG. 5A is a plan view showing an example of an arrangement state of wires contained in a circuit layer in the second embodiment of the invention, and FIG. 5B shows an example of a section along B-B in FIG. 5A. The embodiment is different from the above described first embodiment in that, in the bending area 120, the heat dissipation wire 34 is formed on a first insulating layer 76a covering the drive power supply line 32 and a second insulating layer 76b is formed on the drive power supply line 32 and the heat dissipation wire 34. Note that, in the illustrated example, the insulating layers 76 are formed to integrally cover the plurality of drive power supply lines 32, however, the parallel drive power supply lines 32 may be covered individually by the insulating layers 76.

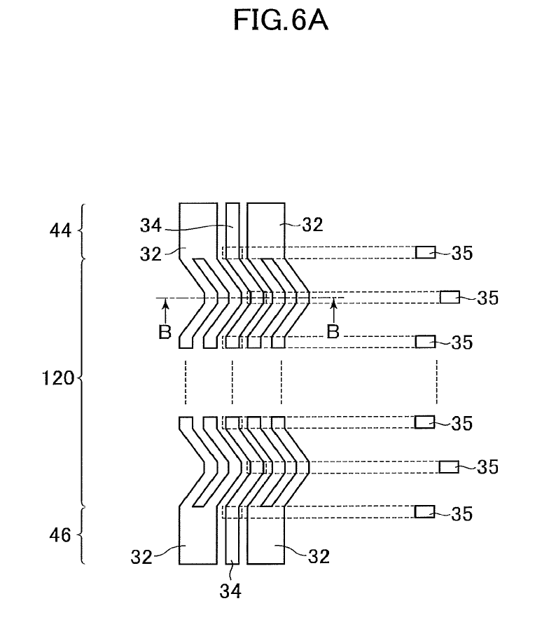

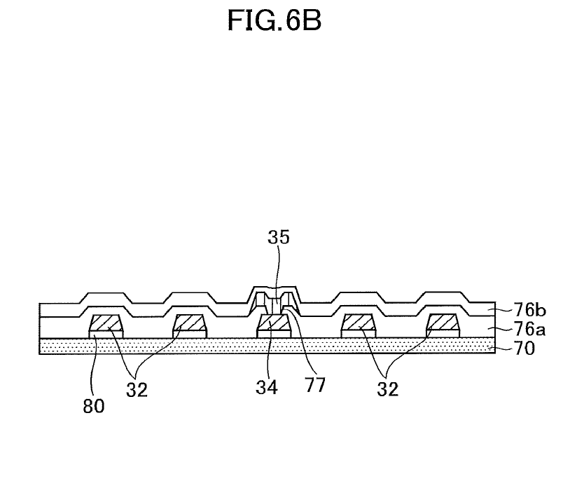

FIG. 6A is a plan view showing an example of an arrangement state of wires contained in a circuit layer in the third embodiment of the invention, and FIG. 6B shows an example of a section along B-B in FIG. 6A. The embodiment is different from the above described first embodiment in that, in the bending area 120, a heat dissipation wiring layer 35 is formed on a first insulating layer 76a covering the drive power supply lines 32 and the heat dissipation wire 34 and a second insulating layer 76b is formed on the structure. The heat dissipation wiring layer 35 is connected to the heat dissipation wire 34 via a contact hole 77 formed in the first insulating layer 76a. In the embodiment, the heat dissipation wiring layer 35 and the drive power supply lines 32 are placed not to overlap in the plan view. Note that, in the illustrated example, the insulating layers 76 are formed to integrally cover the plurality of wires, however, the parallel wires may be covered individually by the insulating layers 76.

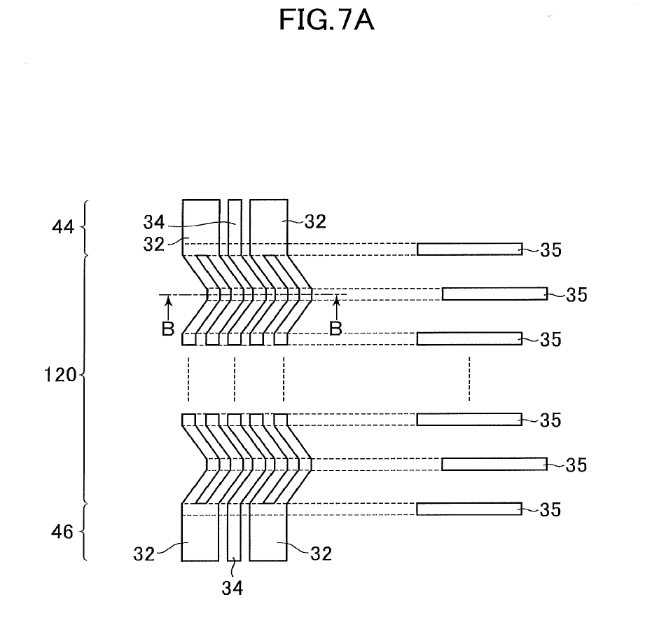

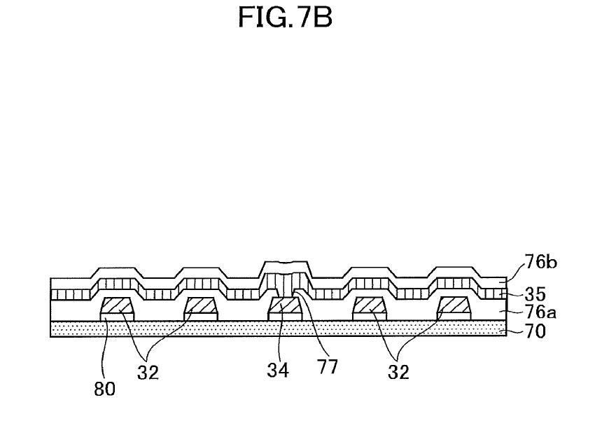

FIG. 7A is a plan view showing an example of an arrangement state of wires contained in a circuit layer in the fourth embodiment of the invention, and FIG. 7B shows an example of a section along B-B in FIG. 7A. The embodiment is different from the above described third embodiment in that the heat dissipation wiring layer 35 is extended in a direction crossing (orthogonal to) the extension direction of the drive power supply lines 32 so that heat dissipation may be improved. The heat dissipation wiring layer 35 is extended in a direction orthogonal to the bending direction of the display panel 40 (the extension direction of the drive power supply lines 32), and thereby, fracture due to bending (deformation stress) may be suppressed. In this case, it is preferable to segment the heat dissipation wire 34 as appropriate. This is because defects due to short circuit between the heat dissipation wiring layer 35 and the drive power supply lines 32 (e.g. short circuit between the drive power supply lines 32, 32) may be suppressed.

The invention is not limited to the above described embodiments, but various changes can be made. For example, the configurations shown in the above described embodiments may be replaced by configurations having substantially the same configurations and the same functions or configurations that may achieve the same purpose.

It will be understood that a person skilled in the art may conceive various modified examples and altered examples within the spirit of the invention and those modified examples and altered examples fall within the scope of the invention. For example, the above described respective embodiments with addition or deletion of component elements or design changes, or addition or omission of steps or condition changes by a person skilled in the art as appropriate fall within the scope of the invention as long as the subject matter of the invention is provided.

What is claimed is:

1. A display device comprising:
a base material having a display area including a plurality of pixels and a peripheral area located outside of the display area;
a pair of wires extending in a first direction from an end part of the base material to the display area of the base material in the peripheral area; and
a second wire located between the pair of wires in the peripheral area,
wherein a power supply voltage to be supplied to the plurality of pixels is applied to the pair of wires,
the power supply voltage to be supplied to the plurality of pixels is not applied to the second wire, and
one of the pair of wires has a first bending portion, the other of the pair of wires has a second bending portion, and the second wire has a third bending portion, the first, second, and third bending portions bending in the same direction as one another.

2. The display device according to claim 1, wherein the second wire dissipates heat generated by at least one of the pair of wires.

3. The display device according to claim 1, wherein a voltage different from the power supply voltage is applied to the second wire.

4. The display device according to claim 1, wherein the base material has a bending area in which the base material is curved in the peripheral area, and
the first bending portion, the second bending portion, and the third bending portion are located in the bending area.

5. The display device according to claim 1, wherein a first power supply voltage is applied to one of the pair of wires, and
a second power supply voltage smaller than the first power supply voltage is applied to the other of the pair of wires.

6. The display device according to claim 1, wherein both of the pair of wires have a first portion having a first width and a second portion having a second width smaller than the first width, and
a width of the second wire adjacent to the first portion is equal to a width of the second wire adjacent to the second portion.

7. The display device according to claim 1, wherein the second wire includes at least one portion extending in a second direction crossing the first direction.

8. The display device according to claim 7, wherein the second wire includes a plurality of the portions.

9. The display device according to claim 1, wherein the second wire is located in the same layer as the pair of wires.

10. The display device according to claim 9, wherein an insulating layer is located on the pair of wires and the second wire,
a third wire is located on the insulating layer, and
the second wire is connected to the third wire via a contact hole located in the insulating layer.

11. The display device according to claim 1, wherein an insulating layer is located on the pair of wires, and
the second wire is located on the insulating layer.

12. A display device comprising:
a base material having a display area including a plurality of pixels and a peripheral area located outside of the display area;
a pair of wires extending in a direction from an end part of the base material to the display area of the base material in the peripheral area; and
a second wire located between the pair of wires in the peripheral area,
wherein a voltage to be supplied to the plurality of pixels is applied to the pair of wires,
the voltage to be supplied to the plurality of pixels is not applied to the second wire,
the base material has a bending area in which the base material is curved in the peripheral area, and
one of the pair of wires has a first bending portion, the other of the pair of wires has a second bending portion, and the second wire has a third bending portion in the bending area, the first, second, and third bending portions bending in the same direction as one another.

13. The display device according to claim 12, wherein the second wire dissipates heat generated by at least one of the pair of wires.

14. The display device according to claim 12, wherein a voltage different from the voltage to be supplied to the plurality of pixels is applied to the second wire.

15. The display device according to claim 12, wherein both of the pair of wires have a first portion having a first width and a second portion having a second width smaller than the first width,
the second portion includes the first bending portion and the second bending portion, and
a width of the second wire adjacent to the first portion is equal to a width of the third bending portion.
